(19) United States
(12) Patent Application Publication
(10) Pub. No.: US 2023/0070973 A1
(43) Pub. Date: Mar. 9, 2023

(54) PACKAGE STRUCTURE, DISPLAY DEVICE AND MANUFACTURING METHOD THEREOF

(71) Applicant: Lextar Electronics Corporation, Hsinchu (TW)

(72) Inventors: Chih-Hao LIN, Hsinchu (TW); Jo-Hsiang CHEN, Hsinchu (TW); Wei-Yuan MA, Hsinchu (TW); Hui-Ru WU, Hsinchu (TW); Min-Che TSAI, Hsinchu (TW); Shiou-Yi KUO, Hsinchu (TW); Jian-Chin LIANG, Hsinchu (TW)

(21) Appl. No.: 17/939,799

(22) Filed: Sep. 7, 2022

Related U.S. Application Data
(60) Provisional application No. 63/241,895, filed on Sep. 8, 2021.

(30) Foreign Application Priority Data
Jun. 28, 2022 (CN) 202210749505.2

(51) Int. Cl. H01L 33/46; H01L 33/62; H01L 33/00

(52) U.S. Cl. CPC H01L 33/46; H01L 33/62; H01L 33/0093; H01L 2933/0025; H01L 2933/0066

(57) ABSTRACT

A package structure, a display device, and manufacturing methods thereof are provided. A package structure includes a conductive element, a first dielectric layer, a redistribution layer, a second dielectric layer, a light-shielding layer, a conductive layer, and a light-emitting diode unit. The first dielectric layer is disposed on the conductive element. The redistribution layer is disposed on the first dielectric layer. The redistribution layer is electrically connected to the conductive element. The second dielectric layer is disposed on the first dielectric layer. The light-shielding layer is disposed on the second dielectric layer. The conductive layer is disposed on the redistribution layer and includes a first conductive portion with a light reflectivity of less than 30%. The light-emitting diode unit is disposed on the conductive layer.

### CROSS REFERENCE TO RELATED APPLICATIONS

This application claims the benefit of U.S. Provisional Application No. 63/241,895, filed on Sep. 8, 2021, and priority of China Patent Application No. CN 202210749505.2, filed on Jun. 28, 2022, which are incorporated by reference herein in their entireties.

### TECHNICAL FIELD

Some embodiments of the present disclosure relate to a package structure, a display device, and manufacturing methods thereof, and, in particular, to a package structure including a first conductive portion, a display device, and manufacturing methods thereof.

### BACKGROUND

To avoid pollution from the external environment and the damage by human, and to achieve certain functions like fixation and heat dissipation, a package structure with light-emitting diode (LED) units is formed. Therefore, the reliability, electrical performance and/or optical performance of a light-emitting diode unit in the package structure are improved.

A light-shielding layer is often disposed in the package structure to avoid light leakage and/or noise interference caused by reflected and refracted light from the LED unit. However, even though the light-shielding layer has been disposed in the package structure, the existing package structure and/or the display device including the package structure may still have problems with light leakage and noise interference due to the limitations of the accuracy and cost of the manufacturing process.

Therefore, although existing package structures and display devices have generally achieved their intended purposes, they have not completely met the requirements placed on them in all respects. Therefore, there are still some problems to be overcome regarding package structure, display device, and the manufacturing methods thereof.

### SUMMARY

In some embodiments, a package structure is provided. The package structure includes a conductive element, a first dielectric layer, a redistribution layer, a second dielectric layer, a light-shielding layer, a conductive layer, and a light-emitting diode unit. The first dielectric layer is disposed on the conductive element. The redistribution layer is disposed on the first dielectric layer. The redistribution layer is electrically connected to the conductive element. The second dielectric layer is disposed on the first dielectric layer. The light-shielding layer is disposed on the second dielectric layer. The conductive layer is disposed on the redistribution layer and includes a first conductive portion with a light reflectivity of less than 30%. The light-emitting diode unit is disposed on the conductive layer.

In some embodiments, a display device is provided. The display device includes a package structure and a target substrate. The package structure includes a conductive element, a first dielectric layer, a redistribution layer, a second dielectric layer, a light-shielding layer, a conductive layer, and a light-emitting diode unit. The first dielectric layer is disposed on the conductive element. The redistribution layer is disposed on the first dielectric layer. The redistribution layer is electrically connected to the conductive element. The second dielectric layer is disposed on the first dielectric layer. The light-shielding layer is disposed on the second dielectric layer. The conductive layer is disposed on the redistribution layer and includes a first conductive portion with a light reflectivity of less than 30%. The light-emitting diode unit is disposed on the conductive layer. In addition, the package structure includes a third dielectric layer and a first positioning element. The third dielectric layer is disposed on the light-emitting diode unit and surrounds the light-emitting diode unit. The first positioning element is disposed on the third dielectric layer. The first dielectric layer has a recess. The target substrate is electrically connected to the conductive element and has a second positioning element corresponding to the recess.

In some embodiments, a method of manufacturing a package structure is provided. The method includes providing a carrier board and providing a patterned photoresist layer on the carrier board. An adhesion layer is provided on the patterned photoresist layer. A conductive element is formed on the adhesion layer. A first dielectric layer is formed on the conductive element. A redistribution layer is formed on the first dielectric layer, wherein the redistribution layer is electrically connected to the conductive element. A second dielectric layer is formed on the first dielectric layer. A light-shielding layer is formed on the second dielectric layer. A conductive layer is formed on the redistribution layer, wherein the conductive layer includes a first conductive portion with a light reflectivity of less than 30%. A light-emitting diode unit is formed on the conductive layer.

In some embodiments, a method of manufacturing a display device is provided. The method includes (a) providing a target substrate, wherein the target substrate has a trench and a positioning element. The method includes (b) providing a package structure, wherein the package structure includes a conductive element; a first dielectric layer disposed on the conductive element and having a recess; a redistribution layer disposed on the first dielectric layer, wherein the redistribution layer is electrically connected to the conductive element; a second dielectric layer disposed on the first dielectric layer; a light-shielding layer disposed on the second dielectric layer; a conductive layer disposed on the redistribution layer and including a first conductive portion with a light reflectivity of less than 30%; and a light-emitting diode unit disposed on the conductive layer. The method includes (c) providing a suspension including the package structure to flow over a top surface of the target substrate. The method includes (d) disposing the package structure in the trench, so that the positioning element of the target substrate is bonded with the recess of the first dielectric layer.

The package structure, the display device, and the manufacturing methods thereof of the present disclosure may be applied in various types of electronic apparatus. In order to make the features and advantages of the present disclosure more understand, some embodiments of the present disclosure are listed below in conjunction with the accompanying drawings, and are described in detail as follows.

### BRIEF DESCRIPTION OF THE DRAWINGS

Through the following detailed description and the accompanying drawings, a person of ordinary skill in the art will better understand the viewpoints of some embodiments of the present disclosure. It should be noted that, in accordance with standard practice in the industry, various features are not drawn to scale and are used for illustration purposes. In fact, the dimensions of the various features may be arbitrarily increased or reduced for clarity of discussion.

FIGS. 1 to 6, 7A, 8A, 9A, 10A, and 11 to 14 are schematic cross-sectional views of the package structures at various stages of the manufacturing method, according to some embodiments of the present disclosure.

FIGS. 7B, 8B, 9B and 10B are schematic top views of the package structures at various stages of the manufacturing method, according to some embodiments of the present disclosure.

FIGS. 15 and 16 are schematic cross-sectional views of the package structures according to other embodiments of the present disclosure.

FIGS. 17 to 19 are schematic cross-sectional views of the package structures at various stages of the manufacturing method according to other embodiments of the present disclosure.

FIG. 20 is a schematic cross-sectional view of the package structure according to other embodiments of the present disclosure.

FIGS. 21 to 24 are schematic cross-sectional views of the package structures at various stages of the manufacturing method according to other embodiments of the present disclosure.

FIG. 25 is a schematic cross-sectional view of the target substrate according to other embodiments of the present disclosure.

FIG. 26 is a schematic cross-sectional view of the display device including the package structure according to other embodiments of the present disclosure.

FIGS. 27 and 28 are schematic cross-sectional views of the package structures at various stages of a fluidic mass transfer process according to other embodiments of the present disclosure.

FIGS. 29 and 30 are schematic cross-sectional views of the package structure according to other embodiments of the present disclosure.

FIGS. 31 to 33 are schematic top views of the package structure according to other embodiments of the present disclosure.

FIGS. 34 to 36 are schematic top views of the package structure according to other embodiments of the present disclosure.

FIGS. 37 and 38 are schematic top views of the package structure according to other embodiments of the present disclosure.

### DETAILED DESCRIPTION

The following disclosure provides many different embodiments or examples for implementing different features of the package structure disclosed herein. Specific examples of each feature and its configuration are described below to simplify the embodiments of the present disclosure. Naturally, these are examples and are not intended to limit the present disclosure. For example, if the description mentions that the first feature is formed on the second feature, it may include an embodiment in which the first feature and second feature are in direct contact, or may include an embodiment in which additional feature is formed between the first feature and the second feature thereby the first feature and the second feature do not directly contact. Furthermore, the present disclosure may repeat reference numerals and/or characters in different embodiments or examples for simplify and clarity and is not intended to represent a relationship between the different embodiments and/or examples discussed above.

Directional terms mentioned herein, such as “on”, “below”, “left”, “right”, and the like, refer to the directions of the drawings. Accordingly, the directional terms are used to illustrate rather than limit the present disclosure.

In some embodiments of the present disclosure, terms related to disposing and bonding, such as “dispose”, “connect”, and the like, unless specifically defined, may refer that two components are in direct contact, or may also refer that two components are not in direct contact wherein another component is disposed therebetween. The terms related to disposing and bonding may also include the embodiments where both components are movable or both components are fixed.

In addition, the “first”, “second”, and the like mentioned in the specification or claims are used to name different components or distinguish different embodiments or scopes and are not used to limit the upper limit or lower limit of the number of the components and are not used to limit the manufacturing order or the arrangement order of the components.

In the following, “about”, “substantially”, and the like mean within 10%, or within 5%, or within 3%, or within 2%, or within 1%, or within 0.5% of a given value or range of values. The given value herein is approximate value. That is, the meaning of “about” or “substantially” may still be implied in the absence of a specific description of “about” or “substantially”.

Unless otherwise defined, all terms (including technical and scientific terms) used herein have the same meaning as commonly understood by a person of ordinary skills in the art. It should be understood that these terms, such as those defined in commonly used dictionaries, should be construed to have meanings consistent with the relevant art and the background or context of the present disclosure, and should not be construed in an idealized or overly formal manner, unless otherwise defined in the embodiments of the present disclosure.

Some variations of the embodiments are described below. In the different drawings and the illustrated embodiments, the same or similar reference numerals are used to designate the same or similar components. It is understood that additional steps may be provided before, during, and after the method, and some of the recited steps may be replaced or deleted for other embodiments of the method.

Herein, directions are not limited to three axes of a rectangular coordinate system, such as the X-axis, Y-axis, and Z-axis, and may be interpreted in a broader sense. For example, the X-axis, the Y-axis, and the Z-axis may be perpendicular to one another, or may represent different directions that are not perpendicular to one another, but the present disclosure is not limited thereto. For convenience of description, hereinafter, the X-axis direction is the first direction D1 (width direction), the Y-axis direction is the second direction D2 (length direction), and the Z-axis direction is the third direction D3 (height direction). In some embodiments, the schematic cross-sectional view described herein is a schematic view of observing the XZ plane, and the schematic top view described herein is a schematic view of observing the XY plane. As used herein, “reflectivity” is defined as the percentage of incident optical power reflected from a material within a given wavelength range.

In some embodiments, the manufacturing method of the package structure of the present disclosure is suitable for a chip first process and a redistribution layer first (RDL first) process. In some embodiments, the manufacturing method of the package structure of the present disclosure is suitable for a pad up process and a pad down process. In some embodiments, the manufacturing method of the package structure of the present disclosure is applicable to anchor-type, tether-type and adhesion-type processes. The adhesion process may use temporary adhesion materials such as adhesion layers, release layers, and the like to manufacture the package structure. For the convenience of description, in the following, an adhesion-type redistribution first process with the conductive pad facing downward is used as an example, but the present disclosure is not limited thereto. In addition, in the present disclosure, the number and size of each component in the drawings are for illustration only, and are not intended to limit the scope of the present disclosure.

In some embodiments, the light-emitting diode unit described in the present disclosure may be or include mini LED, micro LED, quantum dot LED, other suitable light-emitting diodes or a combination thereof, but the present disclosure is not limited thereto. In some embodiments, the LED unit may be a pixel unit including sub-pixel units of different colors, or the LED unit may be a sub-pixel unit. For example, the sub-pixel unit may be a red sub-pixel unit, a green sub-pixel unit, or a blue sub-pixel unit. In some embodiments, the LED unit may further include conductive elements such as metal layers, wires, vias, driving elements such as transistors; functional layers such as insulating layers, interlayer dielectric layers, passivation layers, planarization layers, dielectric layers, other suitable elements or a combination thereof, but the present disclosure is not limited thereto. In the following, the LED unit as a pixel unit including three sub-pixel units of different colors is as an example, but the present disclosure is not limited thereto.

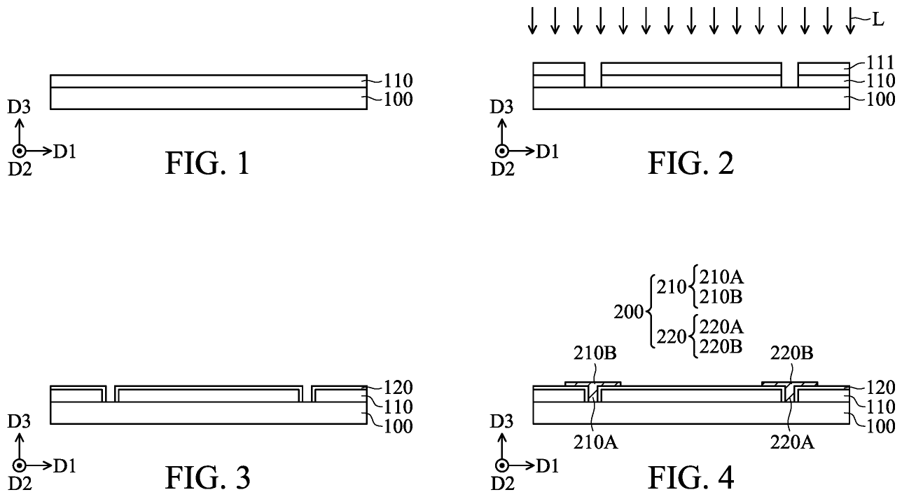

FIG. 1 is a schematic cross-sectional view of a package structure at a stage of the manufacturing method, according to some embodiments of the present disclosure. In some embodiments, a photoresist layer 110 is provided on a carrier 100. In some embodiments, the carrier 100 may include or be a wafer or chip. In some embodiments, the carrier 100 may include or be glass, quartz, sapphire, ceramic, polyimide (PI), polycarbonate (PC), polyethylene terephthalate (PET) carrier, a polypropylene (PP) carrier, a temporary carrier, other suitable carriers, or a combination thereof, but the present disclosure is not limited thereto.

In some embodiments, the photoresist layer 110 may be formed on the carrier 100 by using a chemical vapor deposition (CVD) process, a physical vapor deposition (PVD) process, an atomic layer deposition (ALD) process, a spin coating process, a high density plasma CVD (HDP-CVD) process, other suitable methods or a combination thereof, but the present disclosure is not limited thereto.

FIG. 2 is a schematic cross-sectional view of a package structure at a stage of the manufacturing method, according to some embodiments of the present disclosure. In some embodiments, the photoresist layer 110 is patterned by a first mask 111 to form the patterned photoresist layer 110 on the carrier 100. Specifically, in some embodiments, the first mask 111 is formed on the photoresist layer 110, and an exposure and development process is performed by a light L to pattern the photoresist layer 110. Next, the first mask 111 is removed to expose the patterned photoresist layer 110. In some embodiments, the pattern of the opening of the first mask 111 may correspond to the shape of a subsequently formed conductive element (such as the conductive element 200 in FIG. 4).

FIG. 3 is a schematic cross-sectional view of a package structure at a stage of the manufacturing method, according to some embodiments of the present disclosure. In some embodiments, an adhesion layer 120 is formed on the patterned photoresist layer 110. Specifically, the adhesion layer 120 is formed on the side surface and the top surface of the patterned photoresist layer 110. In other embodiments, the adhesion layer 120 may be blanketly formed on the patterned photoresist layer 110 and the carrier 100. In some embodiments, the adhesion layer 120 may function as a peeling off layer or a release layer. In some embodiments, the adhesion layer 120 may include or be pyrolysis adhesion, ultraviolet (UV) adhesion, light-to-heat conversion (LTHC) adhesion, other suitable cracking-type adhesion layer or a combination thereof, but the present disclosure is not limited thereto. In some embodiments, the adhesion layer 120 may be formed by a coating process or another suitable formation process.

FIG. 4 is a schematic cross-sectional view of a package structure at a stage of the manufacturing method, according to some embodiments of the present disclosure. In some embodiments, a conductive element 200 is formed on the adhesion layer 120 and the carrier 100. In some embodiments, the material of the conductive element 200 may be blanketly formed on the adhesion layer 120 and the carrier 100, and the material of the conductive element 200 may be patterned to form the conductive element 200. In some embodiments, the conductive element 200 may be formed by an electroplating, a dispenser, a screen printing, a spray coating, a chemical vapor deposition, a sputtering, a resistance heating evaporation, an electron beam evaporation, other suitable deposition methods, or a combination thereof, but the present disclosure is not limited thereto.

In some embodiments, the conductive element 200 may include a conductive material. For example, the conductive material may include a metal, a metal nitride, a semiconductor material or a combination thereof, or any other suitable conductive material, but the present disclosure is not limited thereto. In some embodiments, the conductive material may be tin (Sn), copper (Cu), gold (Au), silver (Ag), nickel (Ni), indium (In), platinum (Pt), palladium (Pd), iridium (Ir), titanium (Ti), chromium (Cr), tungsten (W), aluminum (Al), molybdenum (Mo), magnesium (Mg), zinc (Zn), alloys or compounds thereof, other suitable conductive materials, or a combination thereof, but the present disclosure is not limited thereto. In some embodiments, the conductive material may include transparent conductive oxide (TCO). For example, the transparent conductive oxide may include indium tin oxide (ITO), antimony zinc oxide (AZO), tin oxide (SnO), zinc oxide (ZnO), indium zinc oxide (IZO), indium gallium zinc oxide (IGZO), indium tin zinc oxide (ITZO), antimony tin oxide (ATO), other suitable transparent conductive materials or a combination thereof, but the present disclosure is not limited thereto.

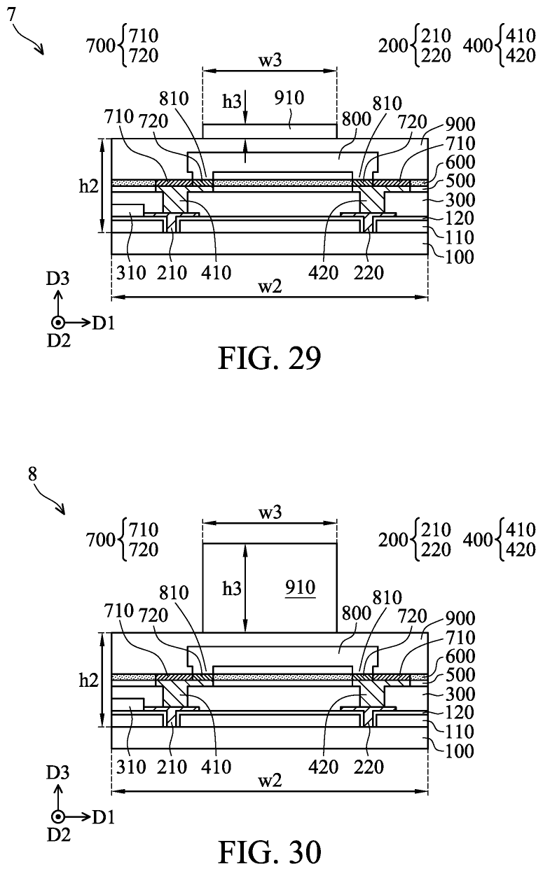

As shown in FIG. 4, in some embodiments, the conductive element 200 may include one or more conductive pads according to electrical requirements. In some embodiments, when the conductive element 200 may include a plurality of conductive pads, the effect of bonding pin holes may be increased. For example, when the conductive element 200 may include a plurality of conductive pads, the reliability of the plurality of conductive pads opposite-bonding (opposite jointing) with subsequent target substrate may be improved. In some embodiments, the conductive element 200 may include a first conductive pad 210, a second conductive pad 220, and other conductive pads (such as a third conductive pad 230 and a fourth conductive pad 240 shown in FIG. 31). In some embodiments, the number and arrangement of the conductive pads may be adjusted according to the electrical properties of the package structure. In some embodiments, at least one of the plurality of conductive pads has a different shape or size than another of the plurality of conductive pads. In some embodiments, at least three of the plurality of conductive pads may have different shapes or sizes. In some embodiments, each of the plurality of conductive pads has a different shape or size. In some embodiments, the first conductive pad 210 and the second conductive pad 220 have different shapes or sizes. Details regarding the plurality of conductive pads of the conductive element 200 will be described below.

As shown in FIG. 4, in some embodiments, the first conductive pad 210 may include a first conductive block 210A and a first conductive film 210B in contact with each other. In some embodiments, the first conductive film 210B may be disposed between the first conductive block 210A and a subsequently formed redistribution layer. In some embodiments, the first conductive block 210A may be closer to the carrier 100 than the first conductive film 210B. In some embodiments, the first conductive block 210A and the first conductive film 210B may be formed in the same process, or the first conductive block 210A and the first conductive film 210B may be sequentially formed in different processes. In some embodiments, the first conductive block 210A and the first conductive film 210B may include the same or different materials. In some embodiments, the first conductive block 210A may include tin (Sn), gold (Au), or a combination thereof, and the first conductive film 210B may include titanium (Ti), platinum (Pt), or nickel (Ni) as barrier layer. In some embodiments, in the third direction D3, the thickness of the first conductive block 210A may be greater than or equal to 1.5 μm and less than or equal to 20 μm. For example, the thickness of the first conductive block 210A may be 1.5 μm, 2 μm, 5 μm, 10 μm, 15 μm, 20 μm or any value between the foregoing values, but the present disclosure is not limited thereto. In some embodiments, in the third direction D3, the thickness of the first conductive film 210B may be greater than or equal to 200 angstroms (Å) and less than or equal to 300 Å. For example, the thickness of the first conductive film 210B may be 200 Å, 220 Å, 240 Å, 260 Å, 280 Å, 300 Å or any value between the foregoing values, but the present disclosure is not limited thereto.

In some embodiments, the area of the bottom surface of the first conductive film 210B may be larger than the area of the top surface of the first conductive block 210A to improve the process margin (process window) of formation of the first conductive film 210B. In other embodiments, the area of the bottom surface of the first conductive film 210B may be equal to the area of the top surface of the first conductive block 210A, so as to improve the process margin for opposite-bonding the first conductive block 210A with the subsequent target substrate.

FIG. 5 is a schematic cross-sectional view of a package structure at a stage of the manufacturing method, according to some embodiments of the present disclosure. In some embodiments, a first dielectric layer 300 is blanketly formed on the conductive element 200 and the adhesion layer 120. In some embodiments, the first dielectric layer 300 covers the top surface and side surface of the conductive element 200. In some embodiments, the first dielectric layer 300 may be formed by a chemical vapor deposition, a sputtering, a resistance heating evaporation, electron beam evaporation, other suitable deposition methods, or a combination thereof.

In some embodiments, the first dielectric layer 300 may be or may include an organic material, an inorganic material, other suitable insulating materials, or a combination thereof, but the present disclosure is not limited thereto. In some embodiments, the first dielectric layer 300 may include or be an Ajinomoto build-up film (ABF), epoxy resin, silicone resin, benzocyclobutene (BCB), polyimide (PI) such as photosensitive polyimide (PSPI), oxides such as silicon oxide (SiOₓ), nitride such as silicon nitride (SiNₓ), oxynitride such as silicon oxynitride (SiOₓN_{y}), other suitable build-up materials, other suitable insulating materials, molding materials, or a combination thereof, but the present disclosure is not limited thereto.

FIG. 6 is a schematic cross-sectional view of a package structure at a stage of the manufacturing method, according to some embodiments of the present disclosure. In the present disclosure, the redistribution layer first process is used as an example, so the redistribution layer is formed first, but the present disclosure is not limited thereto. In some embodiments, the first dielectric layer 300 is patterned to remove a portion of the first dielectric layer 300 and expose the top surface of the conductive element 200. Then, a redistribution layer 400 is formed on the first dielectric layer 300, so that the redistribution layer 400 is electrically connected to the conductive element 200.

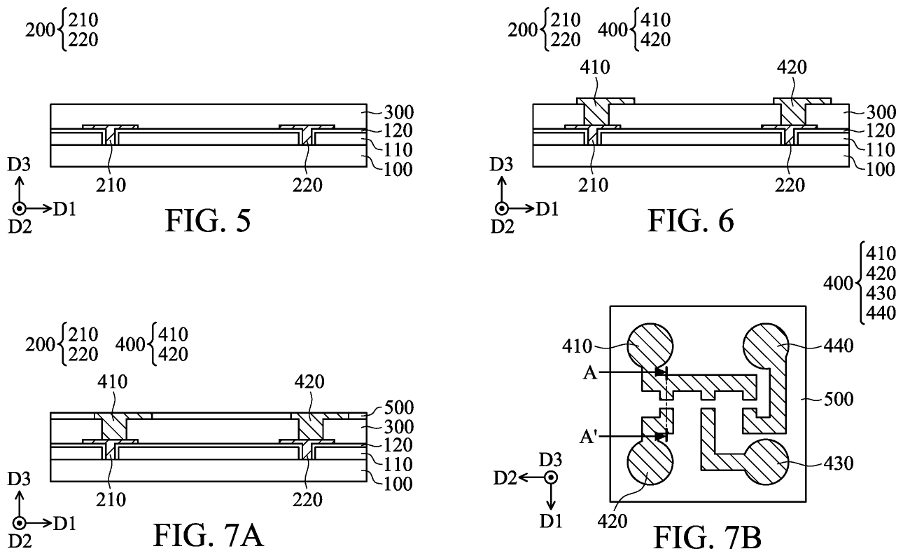

In some embodiments, the redistribution layer 400 may include one or more redistributions according to electrical requirements. In some embodiments, the redistribution layer 400 may include a first redistribution line 410, a second redistribution line 420, and other redistribution lines (such as the third redistribution line 430 and the fourth redistribution line 440 shown in FIG. 7B). In some embodiments, the first redistribution line 410 of the redistribution layer 400 is electrically connected to the first conductive pad 210 of the conductive element 200, and the second redistribution line 420 of the redistribution layer 400 is electrically connected to the second conductive pad 220 of the conductive element 200.

In some embodiments, the materials and formation methods of the redistribution layer 400 and the conductive element 200 may be the same or different. In some embodiments, the redistribution layer 400 may include 3 to 5 stacked layers of titanium-nickel (Ti/Ni) stacked layers, 3 to 5 layers of titanium-platinum (Ti/Pt) stacked layers, or 3 to 5 layers of titanium-aluminum (Ti/Al) stacked layers. In some embodiments, the redistribution layer 400 may further include an intermediate layer (not shown) according to the adhesion strength, physical properties or electrical properties of the redistribution layer 400. In some embodiments, intermediate layers may be disposed in the stacked layers of redistribution layer 400 or between the redistribution layer 400 and the conductive element 200. In some embodiments, the intermediate layer may include chromium (Cr), aluminum (Al), platinum (Pt), nickel (Ni), rhodium (Rh), tungsten (W), tin (Sn), or a combination thereof.

FIGS. 7A and 7B are respectively a schematic cross-sectional view and a schematic top view of the package structure at a stage of the manufacturing method, according to some embodiments of the present disclosure. Wherein, FIG. 7A is a cross-sectional view obtained from line AA′ in FIG. 7B. As shown in FIG. 7A, in some embodiments, a second dielectric layer 500 is blanketly formed on the first dielectric layer 300. In some embodiments, the materials and formation methods of the second dielectric layer 500 and the first dielectric layer 300 may be the same or different. In some embodiments, the top surface of the second dielectric layer 500 is aligned with the top surface of the redistribution layer 400.

As shown in FIG. 7B, in some embodiments, the redistribution layer 400 may include the first redistribution line 410 to the fourth redistribution line 440, and the first redistribution line 410 to the fourth redistribution line 440 may be used as electrodes corresponding to the subsequently bonded light-emitting diode units. For example, the first redistribution line 410 may serve as an anode (such as a common electrode), and the second redistribution line 420 to the fourth redistribution line 440 may serve as cathodes (such as cathodes of different sub-pixel units), but the present disclosure is not limited thereto.

FIGS. 8A and 8B are respectively a schematic cross-sectional view and a schematic top view of the package structure at a stage of the manufacturing method, according to some embodiments of the present disclosure. Wherein, FIG. 8A is a cross-sectional view obtained from line AA′ in FIG. 8B. As shown in FIGS. 8A and 8B, in some embodiments, a light-shielding layer 600 is formed on the second dielectric layer 500. In some embodiments, the light-shielding layer 600 may cover the top surface of the second dielectric layer 500 and may expose the top surface of the redistribution layer 400. In some embodiments, the light-shielding layer 600 may be disposed corresponding to the second dielectric layer 500.

In some embodiments, the light-shielding layer 600 may be a black matrix, black glue, or black photoresist material. In some embodiments, the reflectivity of the light-shielding layer 600 for visible light is less than 30%. For example, the reflectivity of the light-shielding layer 600 for visible light is less than 30%, 25%, 20%, 15%, 10%, 5%, 3%, 1% or any value between the foregoing values, but the present disclosure is not limited thereto. Therefore, in the case where the light-shielding layer 600 has a low reflectivity, reflected visible light may be reduced. In some embodiments, the light-shielding layer 600 may be formed on the second dielectric layer 500 by an attaching process, a coating process, a deposition process, other suitable processes, or a combination thereof.

FIGS. 9A and 9B are respectively a schematic cross-sectional view and a schematic top view of the package structure at a stage of the manufacturing method, according to some embodiments of the present disclosure. Wherein, FIG. 9A is a cross-sectional view obtained from line AA′ in FIG. 9B. As shown in FIG. 9A, in some embodiments, a conductive layer (a conductive layer 700) including a first conductive portion 710 is formed on the redistribution layer 400. In some embodiments, the first conductive portion 710 and the light-shielding layer 600 are disposed on the same layer. In some embodiments, the top surface of the first conductive portion 710 and the top surface of the light-shielding layer 600 are substantially coplanar. In some embodiments, the first conductive portion 710 and the light-shielding layer 600 may be in direct contact. In some embodiments, the first conductive portion 710 may be formed on the redistribution layer 400 and the second dielectric layer 500. In other words, the first conductive portion 710 may overcome the problem that the package structure is limited by the process margin for forming the light-shielding layer 600. For example, since the process margin of the light-shielding layer 600 is limited, the problem of the light leakage or the noise light interference may occur. However, the present disclosure further provides the first conductive portion 710, to provide electrical connection and avoid the light leakage or the noise light interference.

In some embodiments, the light reflectivity of the first conductive portion 710 is less than 30%. Specifically, the reflectivity of the first conductive portion 710 for visible light is less than 30%. For example, the reflectivity of the first conductive portion 710 for visible light is less than 30%, 25%, 20%, 15%, 10%, 5%, 3%, 1% or any value between the foregoing values, but the present disclosure is not limited thereto. Therefore, when the first conductive portion 710 has a low reflectivity, the reflected visible light may be reduced. Thus, the noise light generated form the subsequently disposed LED unit may be reduced, thereby improving the optical properties of the package structure. In other words, by disposing the first conductive portion 710 on the redistribution layer 400, the electrical connection between the redistribution layer 400 and the subsequently formed LED unit is provided while the noise light generated from the light of the LED unit or the ambient light is reduced, thereby improving the light-emitting properties of the package structure. In other embodiments, the reflectivity of the first conductive portion 710 to other types of light may be less than 30%, and the other types of light may correspond to the types of light emitted from the subsequently disposed LED units and/or ambient light. For example, the other type of light may be infrared light.

In some embodiments, as shown in FIG. 9B, the first conductive portion 710 may cover a portion of the top surface of the redistribution layer 400 and expose a portion of the top surface of the redistribution layer 400. In some embodiments, a portion of the first redistribution line 410, a portion of the second redistribution line 420, a portion of the third redistribution line 430, and a portion of the fourth redistribution line 440 may be exposed. For example, the exposed portions of the first redistribution line 410 to the fourth redistribution line 440 may correspond to the contacts of the respective sub-pixel units in the subsequently disposed light-emitting diode. In some embodiments, the first conductive portion 710 may cover at least more than 60% of the top surface of the redistribution layer 400. For example, the first conductive portion 710 may cover at least 60%, 65%, 70%, 75%, 80%, 85%, 90%, 95%, 99% or any value between the foregoing values of the top surface of the redistribution layer 400, but the present disclosure is not limited thereto. Therefore, in the case where the first conductive portion 710 may cover at least more than 60% of the top surface of the redistribution layer 400, the first conductive portion 710 may significantly reduce the noise light interference. In other embodiments, the first conductive portion 710 may cover the whole top surface of the redistribution layer 400, and the contacts in the subsequently formed LED units may be electrically connected to the first conductive portion 710.

In some embodiments, the materials and formation methods of the first conductive portion 710 and the redistribution layer 400 or the conductive element 200 may be the same or different. In some embodiments, the first conductive portion 710 may include black silver, black copper, black nickel, black zinc, other suitable low-reflectivity conductive materials, or a combination thereof, but the present disclosure is not limited thereto. In some embodiments, the first conductive portion 710 may include a transparent conductive oxide. In some embodiments, an organic solderability preservative (OSP) layer (not shown) may be further formed on the first conductive portion 710, in order to protect the first conductive portion 710 under the OSP layer from being oxidized, sulfurized or contaminated.

FIGS. 10A and 10B are respectively a cross-sectional schematic view and a top-view schematic view of the package structure at a stage of the manufacturing method, according to some embodiments of the present disclosure. Wherein, FIG. 10A is a cross-sectional view obtained from line AA′ in FIG. 10B. As shown in FIG. 10A, in some embodiments, a second conductive portion 720 is formed on the redistribution layer 400. In some embodiments, the light reflectivity of the second conductive portion 720 is greater than the light reflectivity of the first conductive portion 710. Specifically, the visible light reflectivity of the second conductive portion 720 is greater than the visible light reflectivity of the first conductive portion 710. In some embodiments, the first conductive portion 710 is disposed on a portion of the redistribution layer 400 and the second conductive portion 720 is disposed on the remaining portion of the redistribution layer 400. In other words, the top surface of the redistribution layer 400 may be completely covered by both the first conductive portion 710 and the second conductive portion 720.

In some embodiments, the light reflectivity of the second conductive portion 720 is greater than 70%. Specifically, the reflectivity of the second conductive portion 720 for visible light is greater than 70%. For example, the reflectivity of the second conductive portion 720 for visible light is greater than 70%, 75%, 80%, 85%, 90%, 95%, 99% or any value between the foregoing values, but the present disclosure is not limited thereto. Therefore, when the second conductive portion 720 has a higher reflectivity, it may be more easily sensed by an optical sensing device such as an automated optical inspection instrument, thereby improving the sensing sensitivity of the optical sensing device. Therefore, the second conductive portion 720 may serve as a positioning element in the subsequent bonding process, thereby increasing the accuracy of the bonding process. In other words, the process margin and reliability may be improved by the disposition of the second conductive portion 720.

In some embodiments, the ratio of the area of the second conductive portion 720 to the first conductive portion 710 (the area of the second conductive portion 720/the area of the first conductive portion 710) may be 0.01, 0.03, 0.05, 0.1, 0.15, 0.2 or any value between foregoing values, but the present disclosure is not limited thereto. In some embodiments, the ratio of the area of the top surface of the redistribution layer 400 covered by the second conductive portion 720 to the area of the top surface of the redistribution layer 400 covered by the first conductive portion 710 (the area covered by the second conductive portion 720/the area covered by the first conductive portion 710) may be 0.01, 0.03, 0.05, 0.1, 0.15, 0.2, or any value between the foregoing values, but the present disclosure is not limited thereto. Therefore, when the first conductive portion 710 and the second conductive portion 720 are used together, the noise light interference may be significantly reduced and the accuracy of the opposite-bonding process may be improved at the same time.

In some embodiments, the materials and formation methods of the second conductive portion 720 and the first conductive portion 710, the redistribution layer 400 or the conductive element 200 may be the same or different. In some embodiments, the second conductive portion 720 may include a material having good compatibility with the contact of the subsequently formed LED unit (such as the contact 810 shown in FIG. 11), so as to improve the reliability of the package structure. In some embodiments, the reflectivity of the first conductive portion 710 is lower than the reflectivity of the second conductive portion 720, and the compatibility between the second conductive portion 720 and the contacts of the LED unit is higher than the compatibility between the first conductive portion 710 and the contacts of the LED unit.

In some embodiments, the second conductive portion 720, the first conductive portion 710, and the light-shielding layer 600 are disposed on and/or in the same layer. That is, the light-shielding layer 600, the first conductive portion 710, and the second conductive portion 720 are aligned with each other. Therefore, the light leakage or noise light interference may be reduced by the first conductive portion 710 and the light-shielding layer 600 together. The electrical connection between the redistribution layer 400 and the subsequently formed LED unit may be provided by the first conductive portion 710 and the second conductive portion 720 together. The accuracy of the opposite-bonding process may also be increased by the second conductive portion 720. In some embodiments, the top surface of the second conductive portion 720, the top surface of the first conductive portion 710 and the top surface of the light-shielding layer 600 are substantially coplanar. In some embodiments, the second conductive portion 720, the first conductive portion 710, and the light-shielding layer 600 may be in direct contact.

FIG. 11 is a schematic cross-sectional view of the package structure at a stage of the manufacturing method, according to some embodiments of the present disclosure. In some embodiments, the light-emitting diode (LED) unit 800 with the contact 810 is formed on the conductive layer 700, so that the LED unit 800 is electrically connected with the conductive layer 700. In some embodiments, the contact 810 may be a conductive pad of the LED unit 800, and the LED unit 800 is electrically connected to other components by the contact 810. In some embodiments, the contact 810 is electrically connected to the conductive layer 700. For example, the contact 810 is in direct contact with the first conductive portion 710 and/or the second conductive portion 720. In some embodiments, the LED unit 800 is a pixel unit, and the pixel unit includes sub-pixel units of different colors. In some embodiments, the LED unit 800 may include a red light-emitting element, a green light-emitting element, a blue light-emitting element, or any combination thereof. For example, the LED unit 800 may include a red light-emitting element, a green light-emitting element, and a blue light-emitting element.

FIG. 12 is a schematic cross-sectional view of the package structure at a stage of the manufacturing method, according to some embodiments of the present disclosure. In some embodiments, a third dielectric layer 900 is formed on the top surface and side surface of the LED unit 800. In some embodiments, the third dielectric layer 900 surrounds the LED unit 800. In some embodiments, the materials and formation methods of the third dielectric layer 900 and the first dielectric layer 300 and/or the second dielectric layer 500 may be the same or different. In some embodiments, the third dielectric layer 900 may include a molding material.

FIG. 13 is a schematic cross-sectional view of the package structure 1 at a stage of the manufacturing method, according to some embodiments of the present disclosure. In some embodiments, a removal process is performed to remove the carrier 100, the patterned photoresist layer 110 and the adhesion layer 120, to expose the bottom surface of the conductive element 200, thereby obtaining the package structure 1. In some embodiments, the removal process may correspond to the material of the adhesion layer 120. For example, when the adhesion layer 120 is a pyrolysis adhesion, the removal process may be a heating process, or when the adhesion layer 120 is an ultraviolet adhesion, the removal process may be an ultraviolet irradiation process.

FIG. 14 is a schematic cross-sectional view of the package structure at a stage of the manufacturing method, according to some embodiments of the present disclosure. In some embodiments, a target substrate TS is provided, and an opposite-bonding process is performed, to electrically connect the LED unit 800 to the target substrate TS by the exposed conductive element 200. In some embodiments, the material of the target substrate TS and the carrier 100 may be the same or different.

For example, in some embodiments, the redistribution layer 400 may include or be tin, copper, gold, silver, nickel, indium, platinum, palladium, iridium, titanium, chromium, tungsten, aluminum, molybdenum, magnesium, zinc, alloys or compounds thereof, and the first conductive portion 710 may include or be black silver, black copper, black nickel or black zinc, so the first conductive portion 710 may reduce the reflectivity of the redistribution layer 400 under the first conductive portion 710. In this embodiment, the target substrate TS may be a black substrate, so as to further reduce the reflectivity. In this embodiment, the second conductive portion 720 may be provided to improve the compatibility between the conductive layer 700 and the contact 810 of the LED unit 800.

For example, in other embodiments, the redistribution layer 400 may include or may be a transparent conductive oxide, such as indium tin oxide, antimony zinc oxide, tin oxide, zinc oxide, indium zinc oxide, indium gallium zinc oxide, indium tin zinc oxide, antimony tin oxide, other suitable transparent conductive materials or a combination thereof, and the target substrate TS may be a black substrate. Therefore, the reflectivity may be reduced by using the transparent conductive oxide with the black substrate. In this embodiment, the first conductive portion 710 may include or be the aforementioned transparent conductive oxide, or the first conductive portion 710 may be omitted. In this embodiment, the conductive element 200 may also include or be the aforementioned transparent conductive oxide. In this embodiment, the second conductive portion 720 may be provided to improve the compatibility between the conductive layer 700 and the contact 810 of the LED unit 800.

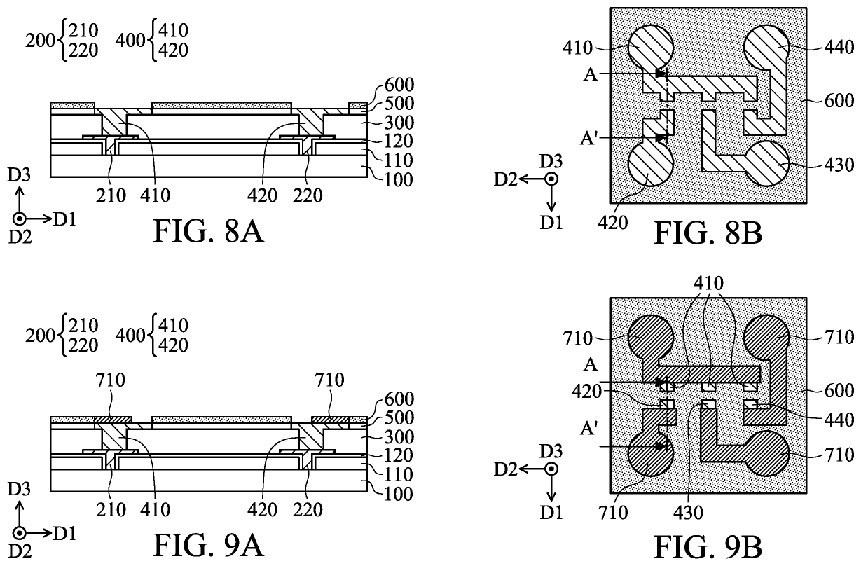

FIG. 15 is a schematic cross-sectional view of the package structure 2 at a stage of the manufacturing method, according to some embodiments of the present disclosure. As shown in FIG. 15, in some embodiments, the first conductive pad 210 may be a different shape and/or size than the second conductive pad 220. In some embodiments, when the area of the bottom surface of the second conductive film of the second conductive pad 220 is equal to the area of the top surface of the second conductive block of the second conductive pad 220, the second conductive pad 220 may have a rectangular cross-section to improve the process margin of the bonding between the second conductive pad 220 and the target substrate.

FIG. 16 is a schematic cross-sectional view of the package structure 3 at a stage of the manufacturing method, according to some embodiments of the present disclosure. As shown in FIG. 16, in some embodiments, the second conductive pad 220 may have a step-shape cross section, so as to improve the bonding strength of the second conductive pad 220 and the target substrate. In detail, since the surface area of the second conductive pad 220 is increased, the friction force and the bonding area may be increased, thereby enhancing the bonding strength. In other embodiments, the first conductive pad 210 and/or the second conductive pad 220 may have a T-shape cross section or another suitable polygonal cross section.

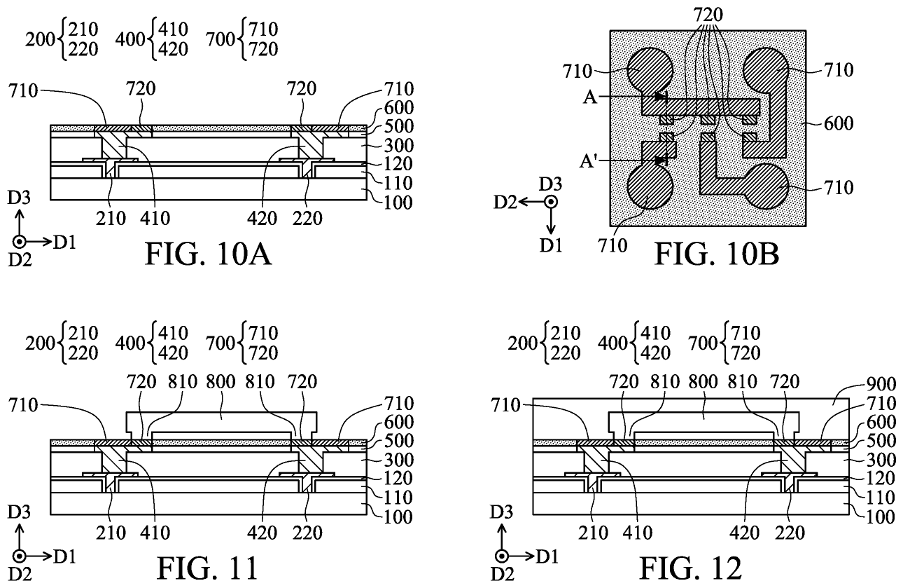

FIGS. 17 to 19 are schematic cross-sectional views of the package structure 4 at various stages in the manufacturing method according to other embodiments of the present disclosure. Since FIGS. 17 to 19 are similar to those shown in FIGS. 1 to 6, 7A, 7B, 8A, 8B, 9A, 9B, 10A, 10B, and 11 to 14, the same or similar elements or descriptions will not be repeated.

As shown in FIG. 17, in some embodiments, a second mask layer 112 is provided on the photoresist layer 110 to pattern the photoresist layer 110. In some embodiments, the second mask layer 112 is a gray tone mask. Specifically, due to the interference and diffraction effects generated by the second mask layer 112, the exposure energy is uneven, so that the top surface of the photoresist layer 110 is irradiated by different exposure energy. Therefore, after exposure, the pattern height of the patterned photoresist layer 110 is different and a specific pattern is formed. Thus, the conductive element 200 with a specific shape may be correspondingly formed. As shown in FIG. 18, in some embodiments, the first conductive block 210A of the first conductive pad 210 and the second conductive block 220A of the second conductive pad 220 may have a triangular cross section. As shown in FIG. 19, the package structure 4 may be obtained.

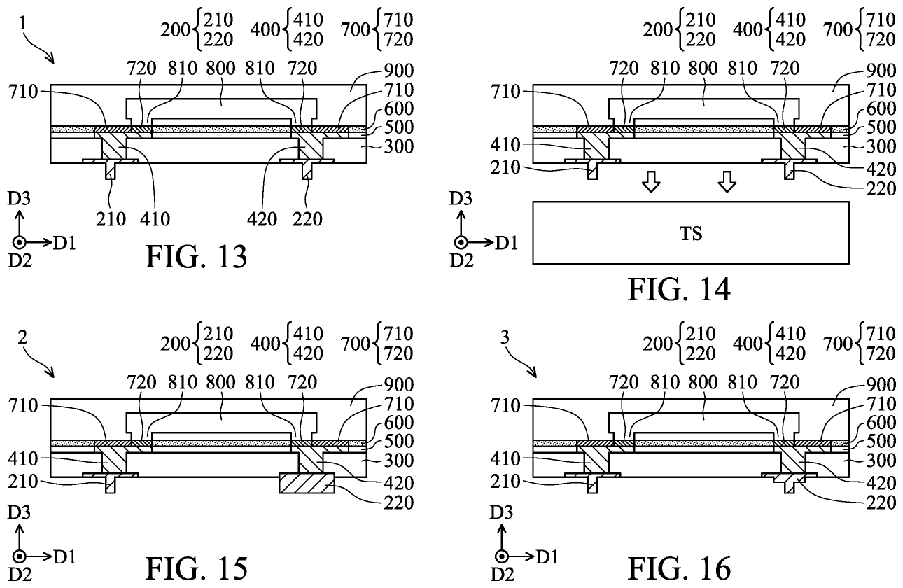

FIG. 20 is a schematic cross-sectional view of the package structure 5 at a stage in the manufacturing method according to other embodiments of the present disclosure. In some embodiments, the first conductive pad 210 and the second conductive pad 220 may have a semicircular cross-section. In other embodiments, the first conductive pad 210 and the second conductive pad 220 may have a fan-shaped cross-section, a platform shape cross-section, an arc shape cross-section, a water drop shape cross-section, a rectangle shape (for example, a rectangle with a side length in the first direction D1 is greater than that in the third direction D3, or a rectangle with a side length in the first direction D1 is smaller than that in the third direction D3) cross-section or another suitable cross-section. In some embodiments, the first conductive block 210A and the second conductive block 220A may be pyramid-shaped, tapered, drill-shaped, or another suitable shape.

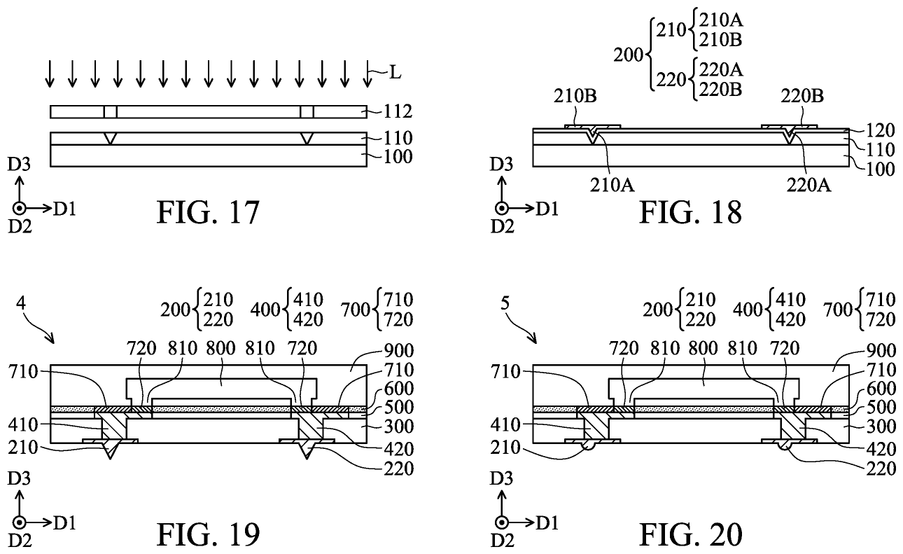

FIGS. 21 to 24 are schematic cross-sectional views of a package structure at various stages in a manufacturing method according to other embodiments of the present disclosure. The process illustrated in FIG. 21 may be performed between FIG. 4 and FIG. 5, or it may be performed after FIG. 18.

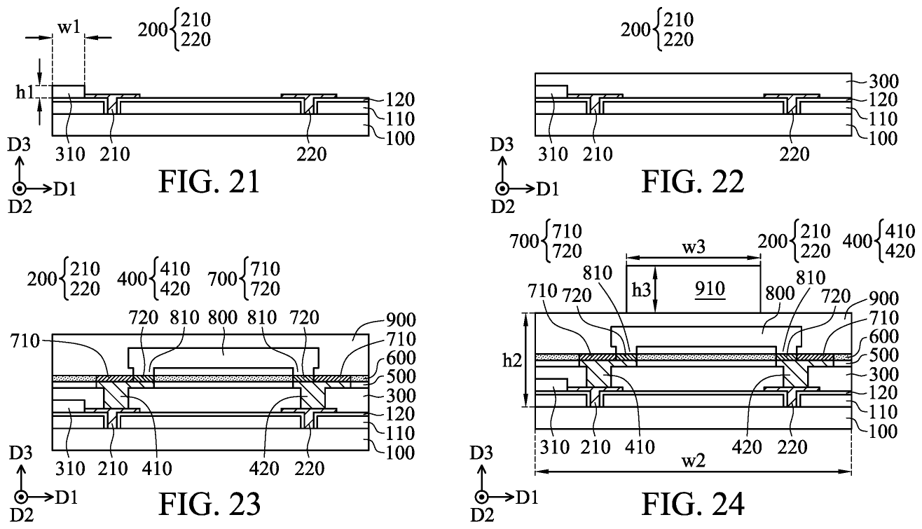

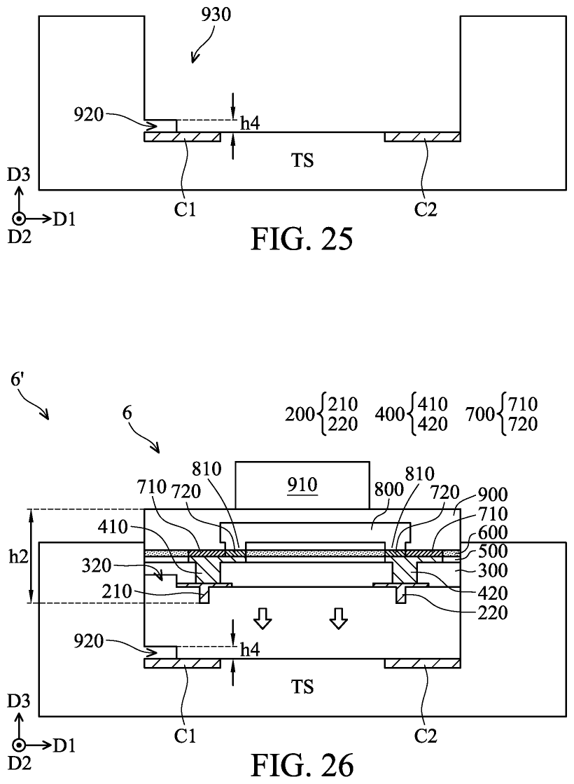

As shown in FIG. 21, in some embodiments, a sacrificial element 310 is formed on the adhesion layer 120. In some embodiments, the sacrificial element 310 may be disposed adjacent to the conductive element 200. In some embodiments, the sacrificial element 310 may include or be a photoresist material or any material that may be removed with adhesion layer 120. In some embodiments, the sacrificial element 310 may have a first height h1 in the third direction D3. In some embodiments, the sacrificial element 310 may have a first width w1 in the first direction D1. Accordingly, the first height h1 and the first width w1 of the sacrificial element 310 may correspond to the height and width of a subsequently formed recess (such as a recess 320 shown in FIG. 26). In some embodiments, in the first direction D1, the sacrificial element 310 may be disposed on one side of the conductive element 200, but the present disclosure is not limited thereto. In other embodiments, in the first direction D1, the sacrificial elements 310 may be disposed on both sides of the conductive element 200. In other embodiments, the sacrificial element 310 may surround the conductive element 200. In some embodiments, the sacrificial element 310 may further include separate portions (not shown). Therefore, the second positioning element (such as a second positioning element 920 in FIG. 25) described later may substantially have a shape corresponding to the sacrificial element 310.

As shown in FIG. 22, in some embodiments, the process shown in FIG. 5 continues. In some embodiments, the first dielectric layer 300 is formed on the sacrificial element 310 and the conductive element 200. The first dielectric layer 300 may cover the top surface and side surface of the sacrificial element 310 and the top surface and side surface of the conductive element 200.

As shown in FIG. 23, in some embodiments, subsequent processing continues. In some embodiments, the redistribution layer 400, the second dielectric layer 500, the light-shielding layer 600, the conductive layer 700, the LED unit 800, and the third dielectric layer 900 are sequentially formed.

As shown in FIG. 24, in some embodiments, a first positioning element 910 is formed on the third dielectric layer 900. In some embodiments, the first positioning element 910 may include or be a photoresist material. In some embodiments, since the first positioning element 910 may be formed on the third dielectric layer 900, it acts as a positioning element for the package structure 6 in the third direction D3. Therefore, the package structure 6 may be bonded in a specific direction on the target substrate. In some embodiments, a buffer layer (not shown) may be further disposed between the first positioning element 910 and the third dielectric layer 900 to improve the compatibility between the first positioning element 910 and the third dielectric layer 900. Then, in some embodiments, a removal process is performed to remove the carrier 100, the patterned photoresist layer 110, the adhesion layer 120, and the sacrificial element 310, thereby forming a recess 320 (referring to FIG. 26) on the bottom surface of the first dielectric layer 300.

In some embodiments, a second height h2 is a distance between the bottom surface of the conductive element 200 and the top surface of the third dielectric layer 900 in the third direction D3, and the third dielectric layer 900 has a second width w2 in the first direction D1. In some embodiments, the first positioning element 910 has a third height h3 in the third direction D3, and the first positioning element 910 has a third width w3 in the first direction D1.

In some embodiments, the ratio of the third width w3 to the second width w2 (third width w3/second width w2) may be greater than 0.32 and less than 0.71. For example, the ratio of the third width w3 to the second width w2 may be 0.33, 0.35, 0.4, 0.5, 0.6, 0.65, 0.7, 0.71 or any value between the foregoing values, but the present disclosure is not limited thereto. In some embodiments, the ratio of the third height h3 to the second height h2 (third height h3/second height h2) may be greater than 0.1 and less than 1. For example, the ratio of the third height h3 to the second height h2 may be 0.11, 0.15, 0.2, 0.4, 0.6, 0.8, 0.95, 0.99 or any value between the foregoing values, but the present disclosure is not limited thereto. In some embodiments, if the ratio of the third width w3 to the second width w2 is not greater than 0.32 and/or the ratio of the third height h3 to the second height h2 is not greater than 0.1, the volume of the first positioning element 910 is too small, so it is difficult to achieve the function of positioning. In detail, although the package structure 6 is in contact with the target substrate, it may not be electrically bonded effectively. In some embodiments, if the ratio of the third width w3 to the second width w2 is not less than 0.71 and/or the ratio of the third height h3 to the second height h2 is not less than 1, the volume of the first positioning element 910 is too large to keep a reasonable processing cost. Besides, the thickness of the package structure is increased and is adverse to the miniaturization applications. In addition, the ratio of the third width w3 to the second width w2 and/or the ratio of the third height h3 to the second height h2 may be adjusted to make the package structure easier to roll and facilitate the fluidic mass transfer process.

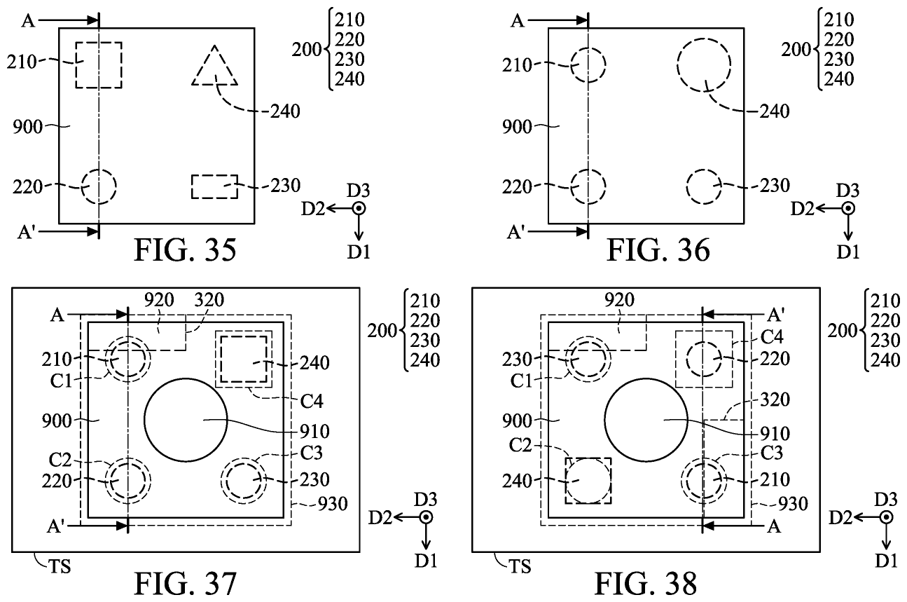

FIG. 25 is a schematic cross-sectional view of a target substrate TS according to other embodiments of the present disclosure. For example, the target substrate TS may be a display substrate, a printed circuit board (PCB), other suitable substrates, or a combination thereof. As shown in FIG. 25, in some embodiments, a target substrate TS is provided. In some embodiments, the target substrate TS may further include connection elements including a first connection element C1, a second connection element C2, and other connection elements (such as a third connection element C3 and a fourth connection element C4 in FIG. 37) to electrically connect the connection element and the conductive element 200. In some embodiments, the materials and formation methods of the first connection element C1 and the second connection element C2 and the conductive element 200 may be the same or different. In some embodiments, the target substrate TS may further include a trench 930 for accommodating the package structure 6, and the first connection element C1 and the second connection element C2 are disposed on the bottom surface of the trench 930.

In some embodiments, the target substrate TS further includes a second positioning element 920 corresponding to the recess 320. In some embodiments, the second positioning element 920 may be disposed in the trench 930. In some embodiments, the second positioning element 920 may be formed by etching and/or by deposition. In some embodiments, the materials of the second positioning element 920 and the target substrate TS may be the same or different. In some embodiments, the second positioning element 920 may have a fourth height h4 in the third direction D3. Accordingly, the fourth height h4 of the second positioning element 920 may be substantially the same as the first height h1 of the sacrificial element 310. In some embodiments, the second positioning element 920 is disposed on the first connection element C1. In some embodiments, a plurality of trenches 930 may be provided in the target substrate TS to accommodate a plurality of the package structures 6 according to requirements. In some embodiments, the plurality of trench 930 may be disposed on the top surface of the target substrate TS in a matrix manner. In this embodiment, the second positioning elements 920 may be provided in plurality, and each of the plurality of second positioning elements 920 may be respectively disposed in each of the plurality of trenches 930.

It should be noted that the first connection element C1 and the second connection element C2 on the target substrate TS have specific electrode polarities (such as cathode/anode) in the present disclosure, thus they need to be connected with specific conductive pads of the conductive elements in the package structure 6 for normal operation. Therefore, the present disclosure appropriately performs the bonding process by disposing the specific conductive pads, the recess 320, the first positioning element 910 and the second positioning element 920.

FIG. 26 is a schematic cross-sectional view of a display device 6′ including the package structure 6 according to other embodiments of the present disclosure. As shown in FIG. 26, in some embodiments, the package structure 6 is bonded with the target substrate TS to obtain a display device 6′. In some embodiments, the package structure 6 and the target substrate TS may be bonded by performing a fluidic mass transfer process or another suitable panel-level packaging (PLP) process. In some embodiments, the fluidic mass transfer process may provide the package structure 6 driving force by using a suspension with a specific flow rate and liquid density. In some embodiments, a suspension including one or more package structure 6 is flowed over the top surface of the target substrate TS, thereby disposing the package structure 6 in the trench 930 of the target substrate TS. In some embodiments, the second positioning element 920 of the target substrate TS are bonded with the recess 320 of the first dielectric layer 300 in the package structure 6. In some embodiments, the second positioning element 920 may be in direct contact with the recess 320. Therefore, the second positioning element 920 may make the target substrate TS and the package structure 6 bond in correct electrode polarity. However, if the package structure 6 is rotated in the first direction D1 or the second direction D2, the second positioning element 920 can block the package structure 6 so that the package structure 6 may not be bonded to the target substrate TS. As shown in FIG. 26, in some embodiments, compared with the LED unit 800, the first positioning element 910 may be far away from the second positioning element 920 of the target substrate TS so that the target substrate TS and the package structure 6 are bonded in correct electrode polarity. Therefore, the first positioning element 910 and/or the second positioning element 920 may improve the yield of the bonding process. The fluidic mass transfer process is described in detail below.

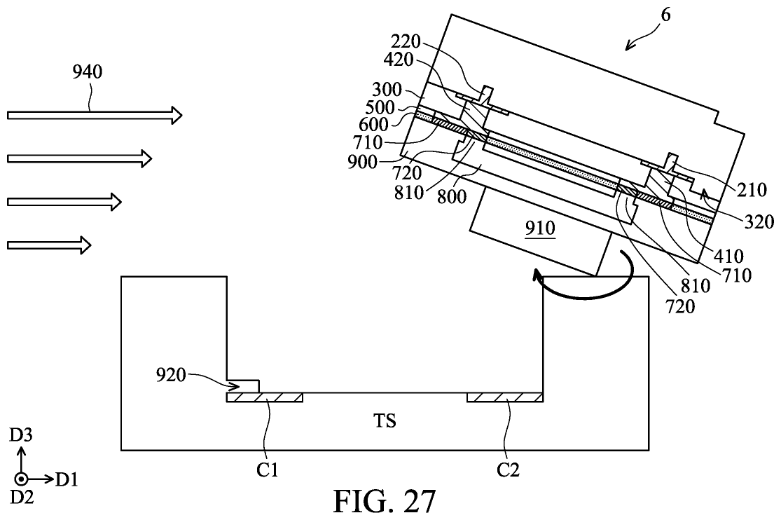

FIGS. 27 and 28 are schematic cross-sectional views of various stages of performing a fluidic mass transfer process of the package structure 6 using the suspension 940 according to other embodiments of the present disclosure. FIGS. 27 and 28 show that the package structure 6 has not been correctly bonded to the target substrate TS. For convenience of description, FIGS. 27 and 28 show that the target substrate TS has only one trench 930, and only one package structure 6 is shown, but the present disclosure is not limited thereto.

As shown in FIG. 27, in some embodiments, the fluidic mass transfer process makes the suspension 940 including the package structures 6 flow over the top surface of the target substrate TS to push the package structures 6 by the suspension 940. In some embodiments, the suspension 940 is a liquid in which package structure 6 is suspended. In some embodiments, when the package structure 6 contacts the top surface of the target substrate TS with the top surface of the first positioning element 910, the suspension 940 makes the package structure 6 roll along the top surface of the target substrate TS. Therefore, the package structure 6 may roll on the target substrate TS along the plane formed by the first direction D1 and the second direction D2 until the package structure 6 falls into any one of the trenches 930 of the target substrate TS. In other words, the first positioning element 910 helps the package structure 6 to roll.

As shown in FIG. 28, in some embodiments, in the fluidic mass transfer process, if the package structure 6 is rolled to make the first positioning element 910 face toward and/or contact the second positioning element 920 of the target substrate TS, the first positioning element 910 blocks the bonding of the package structure 6 and the target substrate TS so that the package structure 6 may not be bonded to the target substrate TS. In addition, since the first positioning element 910 may expand the space between the package structure 6 and the target substrate TS (or be further apart), the first positioning element 910 is helpful for the suspension 940 to flow between the package structure 6 and the target substrate TS in order to provide the driving force for the package structure 6 to continue to roll. Therefore, the package structure 6 can roll to the adjacent trench 930 under the pushing of the suspension 940 and further perform the bonding. For example, the suspension 940 may continue to roll the package structure 6 until the package structure 6 is correctly bonded on the target substrate TS. Therefore, the first positioning element 910 may improve the yield of the opposite-bonding process.

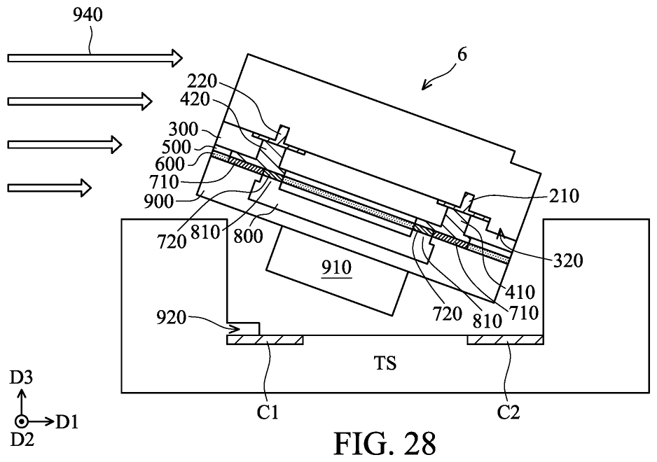

FIGS. 29 and 30 are respectively schematic cross-sectional views of package structures 7 and 8, according to other embodiments of the present disclosure. As shown in FIG. 29, the ratio of the third height h3 to the second height h2 is about 0.15. As shown in FIG. 30, the ratio of the third height h3 to the second height h2 is about 0.95. In some embodiments, any one of the package structures 1 to 8 described in the present disclosure or any combination thereof may be bonded to the target substrate TS to obtain corresponding display devices respectively.

FIG. 31 to FIG. 33 are respectively schematic top views of the package structure according to other embodiments of the present disclosure. As shown in FIG. 31, in some embodiments, when viewed from a top view, the first positioning element 910 has a first area a1, the third dielectric layer 900 has a second area a2, and the ratio of the first area a1 and the second area a2 (first area a1/second area a2) may be greater than 0.1 and less than 0.5. For example, the ratio of the first area a1 to the second area a2 may be 0.11, 0.15, 0.2, 0.25, 0.3, 0.35, 0.4, 0.45, 0.49 or any value between the foregoing values, but the present disclosure is not limited thereto. In some embodiments, if the ratio of the first area a1 to the second area a2 is not greater than 0.1, the volume of the first positioning element 910 is too small. Thus, it is difficult for the first positioning element 910 to achieve positioning function and/or to provide enough driving force for the package structure 6 to continue to roll, thereby reducing the yield of the opposite-bonding process. In some embodiments, if the ratio of the first area a1 to the second area a2 is not less than 0.5, the volume of the first positioning element 910 is too large to keep a reasonable process cost. FIGS. 31 to 33 show embodiments in which the ratios of the first area a1 to the second area a2 are about 0.11, 0.3 and 0.49, respectively.

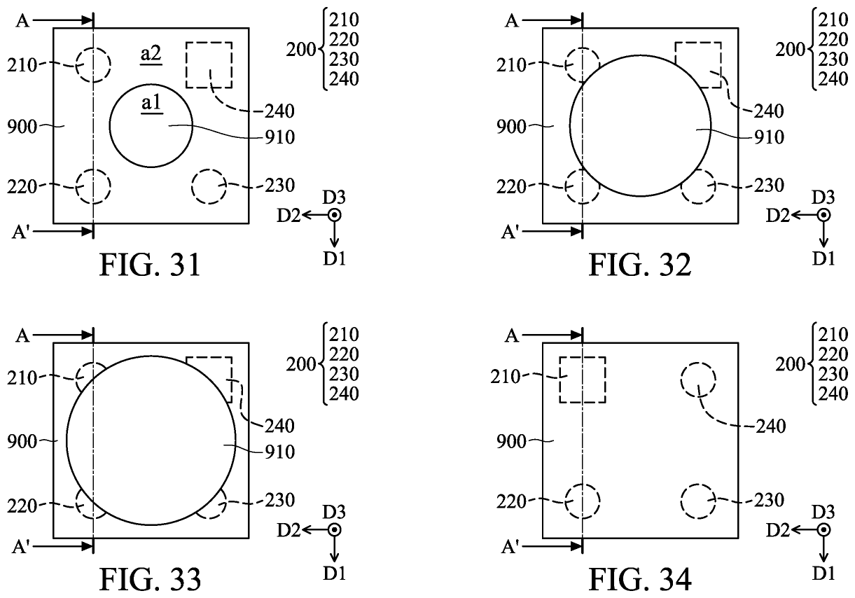

FIGS. 34 to 36 are respectively schematic top views of the package structure according to other embodiments of the present disclosure. As shown in FIG. 34, in some embodiments, the first conductive pad 210 to the fourth conductive pad 240 may have different shapes and sizes. In some embodiments, the second conductive pad 220 to the fourth conductive pad 240 are circular with the same size, and the first conductive pad 210 is a square with a size larger than that of the second conductive pad 220. As shown in FIG. 35, in some embodiments, each of the first conductive pad 210 to the fourth conductive pad 240 is different in size and shape. As shown in FIG. 36, in some embodiments, each of the first conductive pad 210 to the fourth conductive pad 240 has the same shape, but different sizes.

FIG. 37 and FIG. 38 are respectively schematic top views of the package structure according to other embodiments of the present disclosure. FIG. 37 shows a top view in which the package structure and the target substrate TS are bonded with the correct electrode polarity, and FIG. 38 shows a top view in which the package structure and the target substrate TS are bonded with the wrong electrode polarity. As shown in FIG. 37, when the second positioning element 920 is disposed corresponding to the recess 320, the first conductive pad 210 to the fourth conductive pad 240 are electrically connected to the first connection element C1 to the fourth connection element C4, respectively. As shown in FIG. 38, when the second positioning element 920 and the recess 320 are not disposed correspondingly, the first conductive pad 210 to the fourth conductive pad 240 may not be electrically connected to the first connection element C1 to the fourth connection element C4 with the correct electrode polarity.

Thus, according to some embodiments of the present disclosure, a package structure including a first conductive portion having a lower reflectivity is provided, in order to improve the optical properties of the light-emitting diode unit in the package structure. For example, the first conductive portion may reduce noise caused by reflected light or refracted light from external light or light emitted from the light-emitting diode unit. In addition, according to some embodiments of the present disclosure, by disposing the second conductive portion having a higher reflectivity, the accuracy of opposite-bonding process of the LED units is improved. For example, since the opposite-bonding process may be used with an optical sensor to improve the accuracy, the reliability and process margin of the opposite-bonding process may be improved when the second conductive portion may be used as an optical positioning element.

Furthermore, according to some embodiments of the present disclosure, the bonding strength of the package structure is increased by adjusting parameters such as the size, shape, area, and arrangement of the conductive elements of the package structure. In addition, according to some embodiments of the present disclosure, by disposing the first positioning element on the top surface of the package structure, and/or by providing the recess on the first dielectric layer, the target substrate is disposed corresponding to the second positioning element. Thus, the reliability of the plane direction (such as the plane formed by the first direction D1 and the second direction D2) is increased, thereby improving the yield of performing the fluidic mass transfer process on the package structure.

The components in various embodiments of the present disclosure may be arbitrarily combined as long as they do not violate the inventive concept or conflict with each other. In addition, the scope of the present disclosure is not limited to the process, machine, manufacturing, material composition, device, method, and step in the specific embodiments described in the specification. A person of ordinary skill in the art will understand current and future processes, machine, manufacturing, material composition, device, method, and step from the content disclosed in the present disclosure. As long as the current or future processes, machine, manufacturing, material composition, device, method, and step performing substantially the same functions or obtain substantially the same results as the present disclosure, those may be used. Therefore, the scope of the present disclosure includes the above-mentioned process, machine, manufacturing, material composition, device, method, and steps. It is not necessary for any embodiment or claim of the present disclosure to achieve all of the purposes, advantages and/or features disclosed herein.

The foregoing outlines features of several embodiments of the present disclosure, so that a person of ordinary skill in the art may better understand the aspects of the present disclosure. A person of ordinary skill in the art should appreciate that the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a conductive element;
a first dielectric layer disposed on the conductive element;
a redistribution layer disposed on the first dielectric layer, wherein the redistribution layer is electrically connected to the conductive element;
a second dielectric layer disposed on the first dielectric layer;
a light-shielding layer disposed on the second dielectric layer;
a conductive layer disposed on the redistribution layer and comprising a first conductive portion with a light reflectivity of less than 30%; and
a light-emitting diode unit disposed on the conductive layer.

2. The package structure as claimed in claim 1, wherein the conductive layer further comprises a second conductive portion, and a light reflectivity of the second conductive portion is greater than the light reflectivity of the first conductive portion.

3. The package structure as claimed in claim 2, wherein the second conductive portion is disposed on the redistribution layer and is in contact with the first conductive portion.

4. The package structure as claimed in claim 2, wherein the light reflectivity of the second conductive portion is greater than 70%.

5. The package structure as claimed in claim 2, wherein the first conductive portion is disposed on a portion of the redistribution layer, and the second conductive portion is disposed on a remaining portion of the redistribution layer.

6. The package structure as claimed in claim 2, wherein the light-shielding layer, the first conductive portion, and the second conductive portion are aligned with each other.

7. The package structure as claimed in claim 2, wherein the first conductive portion, the light-shielding layer, and the second conductive portion are in contact with each other.

8. The package structure as claimed in claim 1, wherein the conductive element comprises a first conductive pad and a second conductive pad having different shapes or sizes.

9. The package structure as claimed in claim 8, wherein the first conductive pad comprises a first conductive block and a first conductive film in contact with each other, and the first conductive film is disposed between the first conductive block and the redistribution layer, and an area of a bottom surface of the first conductive film is greater than or equal to an area of a top surface of the first conductive block.

10. The package structure as claimed in claim 1, further comprising:
a third dielectric layer disposed on the light-emitting diode unit and surrounding the light-emitting diode unit; and
a first positioning element disposed on the third dielectric layer.

11. The package structure as claimed in claim 10, wherein:
the first positioning element has a first height, a second height being a distance between a bottom surface of the conductive element and a top surface of the third dielectric layer, and a ratio of the first height to the second height is greater than 0.1 and less than 1, and/or
the first positioning element has a first area, the third dielectric layer has a second area, and a ratio of the first area to the second area is greater than 0.1 and less than 0.5.

12. The package structure as claimed in claim 1, wherein the light-emitting diode unit comprises a red light-emitting element, a green light-emitting element, and a blue light-emitting element.

13. A display device, comprising:
the package structure as claimed in claim 1, wherein the first dielectric layer has a recess; and
a target substrate electrically connected to the conductive element and having a second positioning element corresponding to the recess.

14. A method of manufacturing a package structure, comprising:
providing a carrier board;
providing a patterned photoresist layer on the carrier board;
providing an adhesion layer on the patterned photoresist layer;
forming a conductive element on the adhesion layer;
forming a first dielectric layer on the conductive element;
forming a redistribution layer on the first dielectric layer, wherein the redistribution layer is electrically connected to the conductive element;
forming a second dielectric layer on the first dielectric layer;
forming a light-shielding layer on the second dielectric layer;
forming a conductive layer on the redistribution layer, wherein the conductive layer comprises a first conductive portion with a light reflectivity of less than 30%; and
forming a light-emitting diode unit on the conductive layer.

15. The manufacturing method as claimed in claim 14, wherein the formation of the conductive layer further comprises:
forming a second conductive portion on the redistribution layer, so that the second conductive portion is in contact with the first conductive portion, and a light reflectivity of the second conductive portion is greater than the light reflectivity of the first conductive portion.

16. The manufacturing method as claimed in claim 14, further comprising:
forming a third dielectric layer on the light-emitting diode unit; and
performing a removal process to remove the carrier board, the patterned photoresist layer, and the adhesion layer, thereby exposing the conductive element.

17. The manufacturing method as claimed in claim 16, wherein before performing the removal process, the manufacturing method further comprises forming a positioning element on the third dielectric layer.

18. The manufacturing method as claimed in claim 14, wherein before the formation of the first dielectric layer on the conductive element, the manufacturing method further comprises forming a sacrificial element on the adhesion layer.

19. The manufacturing method as claimed in claim 18, wherein a removal process is performed to remove the carrier board, the patterned photoresist layer, the adhesion layer and the sacrificial element, thereby forming a recess on the first dielectric layer.

20. A method of manufacturing a display device, comprising:
(a) providing a target substrate, wherein the target substrate has a trench and a positioning element;
(b) providing a package structure, wherein the package structure comprises:
a conductive element;
a first dielectric layer disposed on the conductive element and having a recess;
a redistribution layer disposed on the first dielectric layer, wherein the redistribution layer is electrically connected to the conductive element;
a second dielectric layer disposed on the first dielectric layer;
a light-shielding layer disposed on the second dielectric layer;
a conductive layer disposed on the redistribution layer and comprising a first conductive portion with a light reflectivity of less than 30%; and
a light-emitting diode unit disposed on the conductive layer;
(c) providing a suspension comprising the package structure to flow over a top surface of the target substrate; and
(d) disposing the package structure in the trench, so that the positioning element of the target substrate is bonded with the recess of the first dielectric layer.
